(19) United States
(12) Patent Application Publication
(10) Pub. No.: US 2013/0153273 A1
(43) Pub. Date: Jun. 20, 2013

(54) STIFFENER AND METHOD FOR MANUFACTURING THE SAME

(71) Applicant: Samsung Electro-Mechanics Co., Ltd., Gyunggi-do (KR)

(72) Inventors: Young Ho Ko, Gyunggi-do (KR); Seung Jae Yeom, Gyunggi-do (KR)

(73) Assignee: Samsung Electro-Mechanics Co., Ltd., Gyunggi-do (KR)

(21) Appl. No.: 13/661,206

(22) Filed: Oct. 26, 2012

(30) Foreign Application Priority Data
Dec. 16, 2011 (KR) 10-2011-0136665

(51) Int. Cl. H05K 1/11; B23K 1/20; H05K 13/00; H05K 1/03; H05K 1/09

(52) U.S. Cl. 174/257; 174/266; 174/258; 427/555; 427/97.7; 228/165

(57) ABSTRACT

Disclosed herein are a stiffener and a method for manufacturing the same. The method includes: forming a metal film on an upper surface or a lower surface of a base layer; forming a plurality of via holes penetrating the base layer and the metal film; and forming a first plating film covering an external surface including an inner surface of each of the via holes.

The double-sided conductive stiffener according to the present invention can support the device by being disposed on the lower surface of the FPCB, and provide a ground structure of the device through the metal film without using the conductive bond or the conductive tape.

### CROSS REFERENCE TO RELATED APPLICATION

This application claims the benefit of Korean Patent Application No. 10-2011-0136665, filed on Dec. 16, 2011, entitled “Stiffener and Method for Manufacturing the same”, which is hereby incorporated by reference in its entirety into this application.

### BACKGROUND OF THE INVENTION

1. Technical Field

The present invention relates to a stiffener and a method for manufacturing the same.

2. Description of the Related Art As portable electronic products become miniaturized, the space in which semiconductor devices are to be mounted is further reduced, and the products become more multi-functional. Therefore, packages are needed to be small and light in order to raise mounting efficiency per unit volume. Due to the above demand, there has been developed and commercialized a chip size package (CSP) having almost chip-scale size.

The trend of package development in the related art is that a chip is continuously stacked and piled on another chip, like a stacked CSP (SCSP), or several semiconductor chips having different functions are arranged within a single package, like a multi chip module (MCM) package, beyond the reduction of package size to chip scale.

In addition, in order to raise efficiency in production, there is a flip chip mounting technology and the like are fast growing that a bare chip is directly bonded to a substrate at the time of mounting, which is called a semiconductor chip without a lead frame, that is, a wireless semiconductor. Also, it is a trend to develop a wafer level package (WLP) technology in which a series of assembling processes such as die bonding, molding, trimming, marking, and the like are completed while several chips are bonded to each other without separating a wafer into individual chips, and then the finished wafer is cut to directly manufacture finished products.

In the electronic products employing these packages, shielding of electro magnetic interference (EMI) is considered as a very important factor.

In particular, clock components of several tens of MHz to several hundreds of MHz are generated in a camera module, and thus, the ground structure of a case for EMI shielding and a stiffener becomes important in the module.

In the prior art, Korean Patent Laid-open Publication No. 2009-0029571 (laid-open published on Mar. 23, 2009) disclosed a metal stiffener, but this metal stiffener has a disadvantage of high price.

Furthermore, a conductive bond or a conductive tape is used for electric connection at the time of adhering this metal stiffener, but the conductive bond is vulnerable to moisture due to hygroscopic property thereof and the conductive tape has problems in adhering strength.

This conductive bond or conductive tape can not be used in a reflow process, and thus, application thereof needs to be performed after completion of the package having components mounted therein.

### SUMMARY OF THE INVENTION

The present invention has been made in an effort to provide a stiffener without using a conductive bond or a conductive tape, in substitution for the metal stiffener of the prior art.

The present invention has also been made in an effort to provide a method for manufacturing the stiffener.

According to a preferred embodiment of the present invention, there is provided a stiffener, including: a base layer; and a first plating film covering an external surface, passing through a plurality of via holes penetrating the base layer.

The stiffener may further include a metal film provided on an upper surface or a lower surface of the base layer.

The stiffener may further include a second plating film covering an external surface of the first plating film to prevent oxidation thereof and improve solderability with a solder.

The base layer may be formed of an insulating material allowing metal plating.

The base layer may be formed of any one of polyimide, an epoxy resin, glass epoxy, fiber reinforced plastic (FRP), glass reinforced polyester (GRP), and carbon fiber reinforced plastic (CRFP).

The second plating film may be formed of any one of tin (Sn), cadmium (Cd), gold (Au), silver (Ag), palladium (Pd), and rhodium (Rh).

The stiffener may be soldered to one surface of a printed circuit board through reflowing of the solder and thereby to provide a ground structure.

According to another preferred embodiment of the present invention, there is provided a method for manufacturing a stiffener, including: forming a metal film on an upper surface or a lower surface of a base layer; forming a plurality of via holes penetrating the base layer and the metal film; and forming a first plating film covering an external surface including an inner surface of each of the via holes.

The method may further include forming a second plating film covering an external surface of the first plating film.

The base layer may be formed of any one of polyimide, an epoxy resin, glass epoxy, fiber reinforced plastic (FRP), glass reinforced polyester (GRP), and carbon fiber reinforced plastic (CRRP), which are insulating materials allowing metal plating.

The forming of the via holes may be performed by using a laser process method or a process method using a drill.

The second plating film may be soldered to one surface of a printed circuit board through a reflow process using a solder.

### BRIEF DESCRIPTION OF THE DRAWINGS

FIG. 1 is a cross-sectional view of a double-sided conductive stiffener according to a preferred embodiment of the present invention;

FIGS. 2A to 2D are process cross sectional views illustrating a method for manufacturing a double-sided conductive stiffener according to a preferred embodiment of the present invention;

FIG. 3 is an exemplary view showing application of the stiffener according to a preferred embodiment of the present invention; and

FIG. 4 is an exemplary view illustrating the soldered state of the stiffener in the exemplary view of FIG. 3.

### DESCRIPTION OF THE PREFERRED EMBODIMENTS

Various objects, advantages and features of the invention will become apparent from the following description of preferred embodiments with reference to the accompanying drawings.

The terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept of the term to describe most appropriately the best method he or she knows for carrying out the invention.

The above and other objects, features and advantages of the present invention will be more clearly understood from the following detailed description taken in conjunction with the accompanying drawings. In the specification, in adding reference numerals to components throughout the drawings, it is to be noted that like reference numerals designate like components even though components are shown in different drawings. Further, terms used in the specification, ‘first’, ‘second’, etc., can be used to describe various components, but the components are not to be construed as being limited to the terms. The terms are only used to differentiate one component from other components. Further, when it is determined that the detailed description of the known art related to the present invention may obscure the gist of the present invention, the detailed description thereof will be omitted.

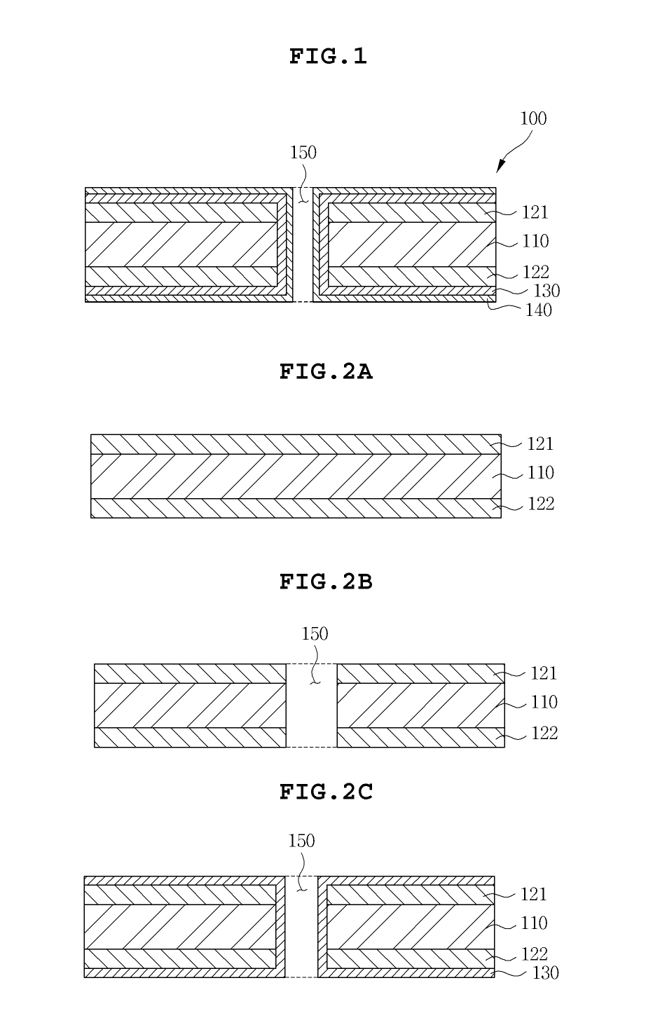

Hereinafter, exemplary embodiments of the present invention will be described in detail with reference to the accompanying drawings. FIG. 1 is a cross-sectional view of a double-sided conductive stiffener according to a preferred embodiment of the present invention.

As shown in FIG. 1, a double-sided conductive stiffener 100 according to a preferred embodiment of the present invention may include a base layer 110, an upper or lower metal film 121 or 122 selectively provided on an upper or lower surface of the base layer 110, a first plating film 130 covering an external surface, passing through a plurality of via holes 150 penetrating the lower or upper lower metal film 121 or 122 and the base layer 110, and, optionally, a second plating film 140 covering an external surface of the first plating film 130.

The base layer 110 is a stiffness layer determining strength of the double-sided conductive stiffener 100, and may be formed of an insulating material allowing metal plating. This base layer 110 may be formed by using, for example, polyimide, an epoxy resin, glass epoxy, fiber reinforced plastic (FRP), glass reinforced polyester (GRP), carbon fiber reinforced plastic (CRRP), or the like.

The upper metal film 121 or the lower metal film 122 may be provided by performing plating on an upper surface or a lower surface of the base layer 110. Specifically, the upper metal film 121 or the lower metal film 122 may be selectively formed of a metal material such as copper or the like, which can reinforce the strength of the base layer 110, and any material that can be used to form the metal film on the upper surface or the lower surface of the base layer 110 through a plating process may be used without limitations.

The first plating film 130 is a metal material film passing through an inner surface of the via hole 150 penetrating the base layer 110 and the upper or lower metal film 121 or 122 and covering an upper surface of the upper metal film 121 and a lower surface of the lower metal film 122. This first plating film 130 is a plating film formed for a ground structure of the double-sided conductive stiffener 100. The solder 300 to be formed above the first plating film 130 is electrically connected to a lower portion of the first plating film 130 passing through a portion of the first plating film 130 disposed in the via hole 150, thereby implementing ground connection through the first plating film 130.

The second plating film 140 is a metal film optionally provided in order to prevent oxidation of the first plating film 130 and improve solderability with the solder 300 to be formed above. The second plating film 140 may be formed by using for example, tin (Sn), cadmium (Cd), gold (Au), silver (Ag), palladium (Pd), rhodium (Rh), or the like. Here, since the second plating film 140 may be a metal film that can be optionally formed, the second plating film 140 does not need to be provided if the first plating film 130 is not oxidized and has good solderability with the solder.

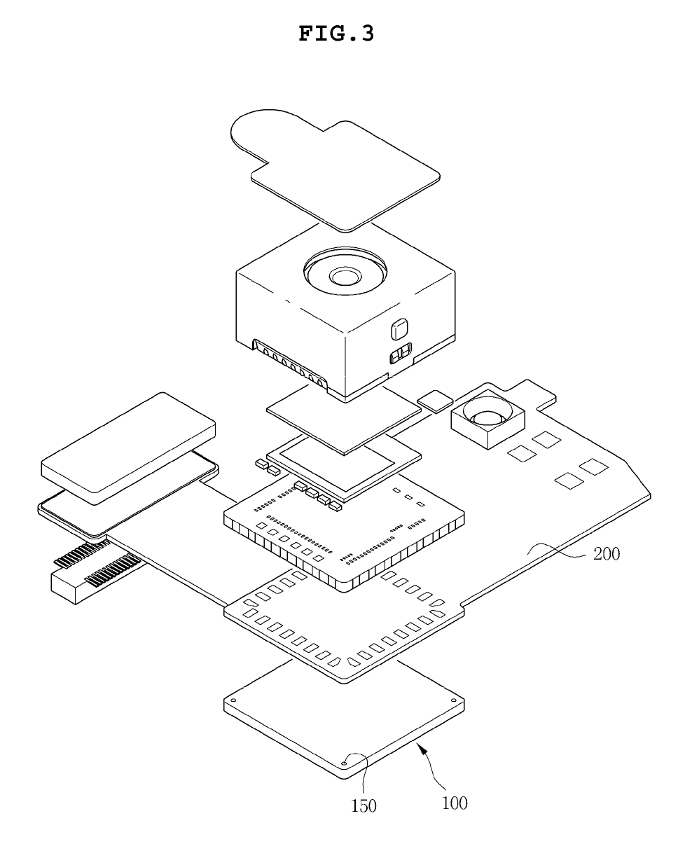

The double-sided conductive stiffener 100 according to a preferred embodiment of the present invention constituted as above, for example, may be provided on a lower surface of an FPCB 200 correspondingly to a camera module while the camera module is mounted on an upper surface of the FPCB 200, as shown in FIG. 3.

This double-sided conductive stiffener 100 can support a device such as the camera module by being disposed on the lower surface of the FPCB 200, and provide a ground structure of the camera module through the first or second metal film, without using the conductive bond or the conductive tape.

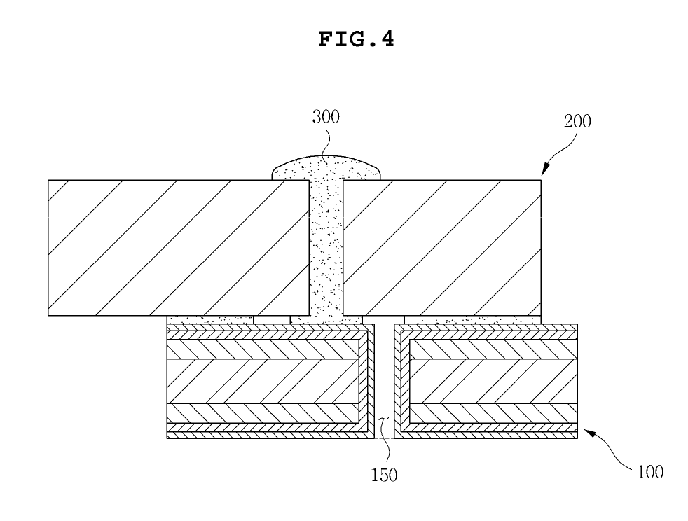

In other words, as shown in FIG. 4, the double-sided conductive stiffener 100 according to a preferred embodiment of the present invention may provide a ground structure of the camera module by reflowing the solder 300 on the FPCB 200 on which the camera module of FIG. 3 is mounted so that the stiffener is soldered to the FPCB 200.

Therefore, the double-sided conductive stiffener 100 allows a ground structure of the camera module to be easily provided, by reflowing the solder 300, without using the conductive bond or the conductive tape.

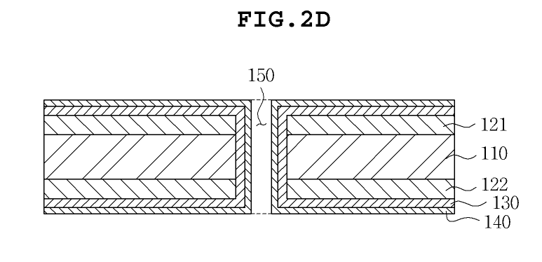

Hereinafter, a method for manufacturing the double-sided conductive stiffener according to a preferred embodiment of the present invention will be described with reference to FIGS. 2A to 2D. FIGS. 2A to 2D are process cross sectional views illustrating a method for manufacturing a double-sided conductive stiffener according to a preferred embodiment of the present invention.

First, as shown in FIG. 2A, in the method for manufacturing a double-sided conductive stiffener according to a preferred embodiment of the present invention, an upper metal film 121 or a lower metal film 122 is formed on an upper surface or a lower surface of a base layer 110.

The base layer 110 is a stiffness layer determining strength of the double-sided conductive stiffener 100, and may be formed by using an insulating material allowing metal plating, for example, polyimide, an epoxy resin, glass epoxy, fiber reinforced plastic (FRP), glass reinforced polyester (GRP), carbon fiber reinforced plastic (CFRP), or the like. Here, the base layer 110 is shown in a plate shape, but is not limited thereto. The base layer 110 may be provided in various shapes depending on the soldered type of the device mounted on the FPCB 200.

The upper metal film 121 or the lower metal film 122 may be selectively formed on the base layer 110. In other words, the metal film may be formed on the upper surface and the lower surface of the base layer 110, or the metal film may be formed on only one of the upper surface and the lower surface of the base layer 110. Certainly, the metal film 121 or 122 may not be formed on the base layer 110.

Then, as shown in FIG. 2B, a plurality of via holes 150 are formed such that they pass through the base layer 110 and the metal film 121 or 122.

Specifically, the via hole 150 is formed by a laser process method using laser or a process method using a drill. The laser process method may be used to form a via hole having a fine diameter of for example 50 μm or less, and the process method using a drill may be used to form the plurality of via holes 150 having a diameter larger than the fine diameter in a computer numerical control (CNC) manner.

After forming the plurality of via holes 150, as shown in FIG. 2C, a first plating film 130 is formed to cover external surfaces of the upper metal film 121 and the lower metal film 122 including an inner surface of the via hole 150.

The first plating film 130 may be formed by using a plating process of a metal material for a ground structure of the double-sided conductive stiffener 100. In other words, electric connection of the first plating film 130 is achieved from an upper surface of the upper metal film 121 to a lower surface of the lower metal film 122 via the inside surface of the via hole 150.

After forming the first plating film 130, as shown in FIG. 2D, the second plating film 140 is optionally formed to cover an external surface of the first plating film 130.

Specifically, as the second plating film 140, a film made of a metal material such tin (Sn), cadmium (Cd), gold (Au), silver (Ag), palladium (Pd), rhodium (Rh), or the like, may be formed on the external surface of the first plating film 130 by a plating process.

This second plating film 140 may be optionally provided in order to prevent oxidation of the first plating film 130 and improve solderability to the solder 300 to be formed above. Certainly, the second plating film 140 need not be formed if the first plating film 130 is not oxidized and has a good solderability with the solder.

Then, the thus obtained double-sided conductive stiffener 100 including the second plating film 140 is soldered to a lower surface of an FPCB 200 by a reflow process using the solder 300, without using a conductive bond or a conductive tape.

In other words, as shown in FIG. 3, in a case where a device such as a camera module is mounted on an upper surface of the FPCB 200, the double-sided conductive stiffener 100 according to a preferred embodiment of the present invention can be easily soldered to the lower surface of the FPCB 200 by reflowing the solder 300.

Therefore, the double-sided conductive stiffener 100 according to a preferred embodiment of the present invention can easily provide the ground structure even without using the conductive bond or the conductive tape, in substitution for the metal stiffener in the prior art.

The double-sided conductive stiffener according to the present invention can support the device by being disposed on the lower surface of the FPCB, and provide a ground structure of the device through the metal film without using the conductive bond or the conductive tape.

Further, according to the method for manufacturing a double-sided conductive stiffener according to the present invention, the double-sided conductive stiffener can be easily obtained by low costs, in substitution for the metal stiffener of the prior art.

Although the spirit of the present invention was described in detail with reference to the preferred embodiments, it should be understood that the preferred embodiments are provided to explain, but do not limit the spirit of the present invention.

Also, it is to be understood that various changes and modifications within the technical scope of the present invention are made by a person having ordinary skill in the art to which this invention pertains.

What is claimed is:

1. A stiffener, comprising:
a base layer; and
a first plating film covering an external surface, passing through a plurality of via holes penetrating the base layer.

2. The stiffener as set forth in claim 1, further comprising a metal film provided on an upper surface or a lower surface of the base layer.

3. The stiffener as set forth in claim 1, further comprising a second plating film covering an external surface of the first plating film to prevent oxidation thereof and improve solderability with a solder.

4. The stiffener as set forth in claim 1, wherein the base layer is formed of an insulating material allowing metal plating.

5. The stiffener as set forth in claim 1, wherein the base layer is formed of any one of polyimide, an epoxy resin, glass epoxy, fiber reinforced plastic (FRP), glass reinforced polyester (GRP), and carbon fiber reinforced plastic (CRFP).

6. The stiffener as set forth in claim 3, wherein the second plating film is formed of any one of tin (Sn), cadmium (Cd), gold (Au), silver (Ag), palladium (Pd), and rhodium (Rh).

7. The stiffener as set forth in claim 1, wherein the stiffener is soldered to one surface of a printed circuit board through reflowing of the solder and thereby to provide a ground structure.

8. The stiffener as set forth in claim 3, wherein the stiffener is soldered to one surface of a printed circuit board through reflowing of the solder and thereby to provide a ground structure.

9. A method for manufacturing a stiffener, comprising:
forming a metal film on an upper surface or a lower surface of a base layer;
forming a plurality of via holes penetrating the base layer and the metal film; and
forming a first plating film covering an external surface including an inner surface of each of the via holes.

10. The method as set forth in claim 9, further comprising forming a second plating film covering an external surface of the first plating film.

11. The method as set forth in claim 9, wherein the base layer is formed of any one of polyimide, an epoxy resin, glass epoxy, fiber reinforced plastic (FRP), glass reinforced polyester (GRP), and carbon fiber reinforced plastic (CRRP), which are insulating materials allowing metal plating.

12. The method as set forth in claim 9, wherein the forming of the via holes is performed by using a laser process method or a process method using a drill.

13. The method as set forth in claim 9, wherein the second plating film is soldered to one surface of a printed circuit board through a reflow process using a solder.
